(19) United States
(12) Patent Application Publication
(10) Pub. No.: US 2008/0003708 A1
(43) Pub. Date: Jan. 3, 2008

(54) Method of processing sapphire substrate

(76) Inventors: Hitoshi Hoshino, Tokyo (JP); Koji Yamaguchi, Tokyo (JP); Kenji Furuta, Tokyo (JP); Hiroshi Morikazu, Tokyo (JP); Ryugo Oba, Tokyo (JP); Yukio Morishige, Tokyo (JP)

Correspondence Address: WENDEROTH, LIND & PONACK, L.L.P., 2033 K STREET N. W., SUITE 800, WASHINGTON, DC, 20006-1021, US

(21) Appl. No.: 11/819,673

(22) Filed: Jun. 28, 2007

(30) Foreign Application Priority Data
Jun. 30, 2006 (JP) 2006-181973

(51) Int. Cl. H01L 21/30

(52) U.S. Cl. 438/33; 257/E21.237

(57) ABSTRACT

To provide a method of processing a sapphire substrate, where reduction in luminance of light emitting devices can be suppressed if a sapphire substrate is divided into individual light emitting devices by irradiation of a laser beam, a pulsed laser beam having a small pulse energy of 0.6 μJ to 10 μJ, and an extremely small pulse width in a range of femto-second is irradiated to the sapphire substrate while a condensing point is positioned within each of regions corresponding to predetermined division lines on the sapphire substrate so that affected zones are formed, thereby the laser beam can be irradiated even at a high peak power density of 4×10¹³ W/cm² to 5×10¹⁵ W/cm², consequently each of the affected zones can be formed at only a desired condensing point within the sapphire substrate, and necessary processing can be performed while damage to nitride semiconductors or the sapphire substrate is minimized.

### BACKGROUND OF THE INVENTION

1. Field of the Invention

The present invention relates to a method of processing a sapphire substrate on which nitride semiconductors are stacked to form a plurality of light emitting devices.

2. Related Art

In a wafer on which nitride semiconductors such as GaN based nitride semiconductors are stacked on a sapphire substrate, and a plurality of light emitting devices such as light emitting diodes (LED) are formed while being partitioned by predetermined division lines, a laser beam is irradiated to regions corresponding to the predetermined division lines so that division grooves are formed. Then, the wafer is divided into individual light emitting devices used for electronic instruments such as a mobile phone, a personal computer, and sound equipment.

The sapphire substrate is comparatively hard to be divided by a dicing machine configured with a cutting blade as a dividing tool because of high Mohs hardness, and a technique of dividing the sapphire substrate using a laser beam is proposed and practically used (for example, see JP-A-58-44738, JP-A-10-305420, and JP-A-2004-9139).

Here, as described later, a light emitting device (for example, LED) using gallium nitride (GaN) based compound semiconductors or the like as the nitride semiconductors is configured by sequentially stacking a GaN based buffer layer, an n-type GaN based layer, an InGaN based active layer, and a p-type GaN based buffer layer on the sapphire substrate, then appropriately etching a surface, and then forming an n-type electrode and a p-type electrode on the surface; and the light emitting device is in a structure where a current is flowed from the p-type electrode to the n-type electrode, thereby light having a predetermined wavelength is ejected from the InGaN based active layer. In this case, in the light emitting device, the InGaN based active layer emits light such that light is ejected in a ratio of about 70% from side faces, about 10% from a side of the nitride semiconductors (surface), and about 20% to a back (sapphire substrate) side. Moreover, an adhesive tape is adhered to the side of a wafer surface (nitride semiconductor layer) on which a plurality of light emitting devices are formed, and a laser beam is irradiated from the back (sapphire substrate) side to form the division grooves.

However, as shown in JP-A-58-44738, JP-A-10-305420, and JP-A-2004-9139, there is a difficulty that when the laser beam is irradiated to the regions corresponding to the predetermined division lines on the sapphire substrate to advance melt by heating of the regions and form the division grooves for dividing the substrate into individual light emitting devices, the periphery of each of the light emitting devices is abraded, resulting in reduction in luminance, consequently a light emitting device having high quality cannot be provided. That is, a laser beam, which may not affect an objective processing point, is transmitted by the sapphire substrate and irradiated to part of the nitride semiconductors, causing damage to the nitride semiconductors, such as melt of the nitride semiconductors, thereby intrinsic light emission of the active layer is reduced, resulting in degradation in capability of the light emitting device.

Moreover, as shown in JP-A-58-44738, JP-A-10-305420, and JP-A-2004-9139, in the case of a laser processing method in which a laser beam is irradiated from a back side of the sapphire substrate so that the back side is melted by heating, a processing traces due to adhesion of a substance, which was melted by heating and then re-coagulated, are widely produced on a section after laser processing. In the light emitted from a light emitting surface of an active layer of a light emitting device, there is light that temporarily enters the sapphire substrate and then goes out of the substrate, and such light is attenuated at portions of the processing traces on the sapphire substrate. Therefore, light extraction efficiency is reduced, leading to decrease in total luminance of the light emitting device.

### SUMMARY OF THE INVENTION

The invention was made in the light of the above, and an object of the invention is to provide a method of processing a sapphire substrate, in which even if a sapphire substrate is irradiated with a laser beam and thus divided into individual light emitting devices, reduction in luminance of the light emitting devices can be suppressed.

To overcome the above difficulties and achieve the object, a method of processing a sapphire substrate according to the invention is a method for forming affected zones within a plurality of predetermined division lines of light emitting devices, which are formed by stacking nitride semiconductors on a sapphire substrate, using a laser processing machine having a chuck table for holding a wafer, a laser beam irradiation unit for irradiating a pulsed laser beam having a wavelength transmitted by the wafer held on the chuck table, a processing feed unit for relatively feeding the chuck table and the laser beam irradiation unit for carrying out a process, and an indexing feed unit for relatively feeding the chuck table and the laser beam irradiation unit to indexed points sequentially: wherein the pulsed laser beam is irradiated at a processing condition satisfying a wavelength of the pulsed laser beam of 1 μm to 2 μm, pulse energy of 0.6 μJ to 10 μJ, pulse energy density of 40 J/cm² to 5 kJ/cm², and peak power density at condensing point of 4×10¹³ W/cm² to 5×10¹⁵ W/cm², while a condensing point is positioned within each of regions corresponding to the predetermined division lines on the sapphire substrate, so that the affected zones are formed.

Moreover, another method of processing a sapphire substrate according to the invention includes the method of the embodiment of the invention, wherein when it is assumed that repetition frequency of the pulsed laser beam is X Hz, condensing spot size of the pulsed laser beam is D mm, and feed rate by the processing feed unit is V mm/s, V/X is 2D to 5D.

Preferably, the repetition frequency X is 10 Hz to 1 MHz, and feed rate V is 10 mm/s to 1000 mm/s.

Preferably, after the affected zones are formed within the sapphire substrate, the sapphire substrate is applied with external force to be divided along the predetermined division lines.

According to the method of processing a sapphire substrate according to the invention, since a pulsed laser beam having a small pulse energy of 0.6 μJ to 10 μJ, and an extremely small pulse width in a range of femto-second is irradiated to the substrate while a condensing point is positioned within each of regions corresponding to predetermined division lines on the sapphire substrate so that affected zones are formed, the laser beam can be irradiated even at a high peak power density of 4×10¹³ W/cm² to 5×10¹⁵ W/cm², consequently each of the affected zones can be formed at only a desired condensing point within the sapphire substrate, the affected zones being reduced in strength so as to be trigger of division due to applied external force. Therefore, necessary processing can be performed while damage to the nitride semiconductors or the sapphire substrate is minimized. Accordingly, an advantage is exhibited, that is, reduction in luminance of the light emitting devices, which are dividedly formed, can be controlled to be extremely small, consequently a light emitting device having high quality can be provided.

### BRIEF DESCRIPTION OF THE DRAWINGS

FIG. 1 is a perspective view showing an example of a configuration of a wafer applied with a method of processing a sapphire substrate according to an embodiment of the invention;

FIG. 2 is a perspective view showing an example of a basic configuration of each light emitting device;

FIG. 3 is a partial section view of FIG. 2;

FIG. 4 is a perspective view showing a configuration of part of a laser processing machine;

FIG. 5 is a block diagram showing an example of a configuration of a laser beam irradiation unit;

FIG. 6 is a perspective view showing a portion near a chuck table for explaining an affected-zone formation process;

FIG. 7A is an explanatory view showing beginning of a laser beam irradiation process;

FIG. 7B is an explanatory view showing the end of the laser beam irradiation process;

FIG. 8 is an explanatory view showing a formation condition of affected zones in an enlarged manner;

FIG. 9 is an explanatory view showing a space between spots;

FIG. 10 is a perspective view showing a division process using a tape expanding machine;

FIG. 11 is a schematic section view showing tape expansion operation; and

FIG. 12 is a section view showing an example of division by one predetermined division line as a modification.

### DETAILED DESCRIPTION OF THE PREFERRED EMBODIMENTS

Hereinafter, a method of processing a sapphire substrate as the best mode for carrying out the invention is described with reference to drawings.

FIG. 1 is a perspective view showing an example of a configuration of a wafer applied with the method of processing a sapphire substrate according to the embodiment. The wafer 1 is formed in a disk shape with a sapphire substrate 11 as a base, in which nitride semiconductors are stacked on the sapphire substrate 11 and a plurality of light emitting devices 12 such as light emitting diodes (LED) are formed while being partitioned by predetermined division lines 13 in a grid pattern.

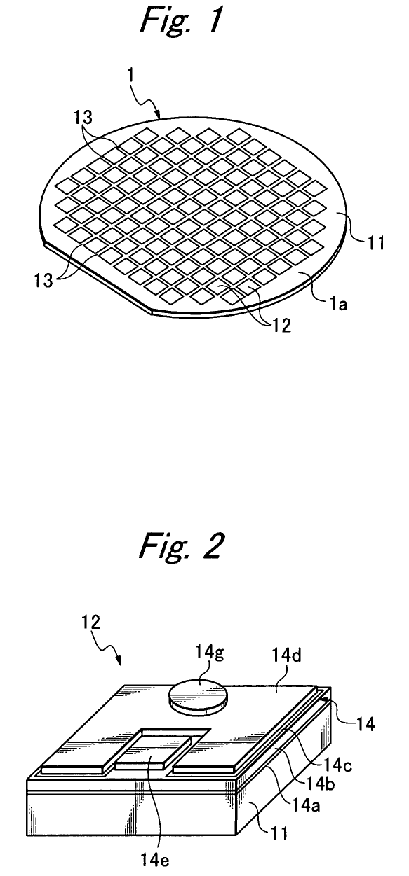

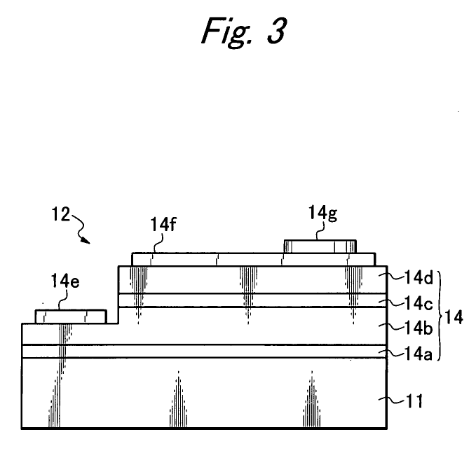

FIG. 2 is a perspective view showing an example of a basic configuration of each light emitting device 12, and FIG. 3 is a section view of part of the device. The light emitting device 12 is formed by stacking nitride semiconductors 14 such as GaN or InGaN, the semiconductors being gallium nitride (GaN) based compound semiconductors, on the sapphire substrate 11. For example, a GaN based buffer layer 14a is formed as an epitaxial layer on the sapphire substrate 11, and furthermore, an n-type GaN based layer 14b, an InGaN based active layer 14c, and a p-type GaN based layer 14d are sequentially stacked so that a PN junction is configured. Then, a partial area at a surface side is appropriately etched to expose a surface of the n-type GaN based layer 14b, and an n-type electrode 14e is formed on a surface of the n-type GaN based layer 14b, and a p-type electrode 14g is formed on a surface of the p-type GaN based layer 14d via a transparent electrode 14f, thereby the light emitting device is configured. Here, while the sapphire substrate 11 has a thickness of about 80 μm to 90 μm, a layer of the nitride semiconductors 14 has a thickness of about 10 μm.

In such a light emitting device 12, a current is flowed from the p-type electrode 14g to the n-type electrode 14e, thereby light having a predetermined wavelength is ejected from the InGaN based active layer 14c. Moreover, in the light emitting device 12, the InGaN based active layer 14c emits light such that light is ejected in a ratio of about 70% from side faces, about 10% from a side of the nitride semiconductors 14 (surface), and about 20% to a back (sapphire substrate 11) side, and it is important that divided surfaces of the nitride semiconductors 14 or the sapphire substrate 11 are not damaged by an irradiated laser beam to prevent reduction in luminance in division processing into the light emitting devices 12 by laser beam irradiation, as described later.

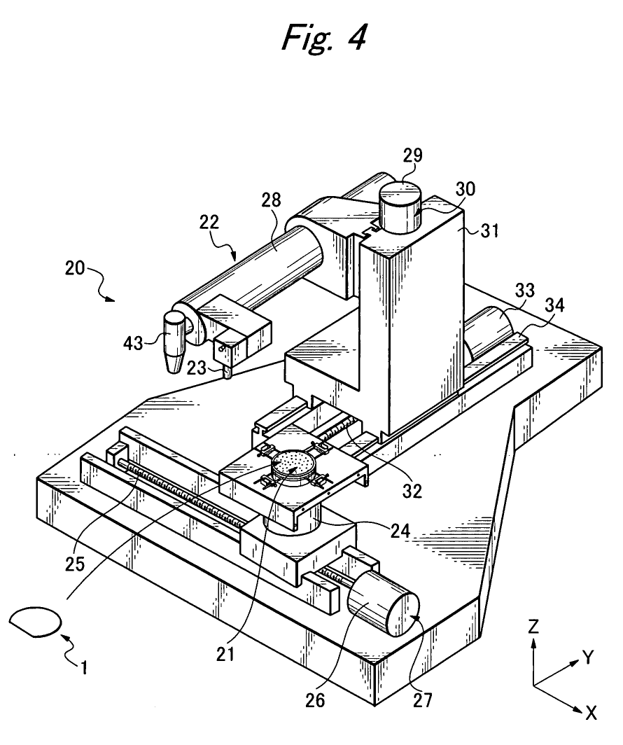

Hereinafter, regarding such a wafer 1, description is made on a method of processing the sapphire substrate 11 for dividing the wafer 1 into the light emitting devices 12. To divide the wafer 1 into individual light emitting devices 12, an affected-zone formation process is carried out, in which a pulsed laser beam having a wavelength transmitted by the sapphire substrate 11 is irradiated along the predetermined division lines 13, thereby affected zones are formed along the predetermined division lines 13 within the sapphire substrate 11. The affected-zone formation process is carried out using a laser processing machine as shown in FIGS. 4 to 6.

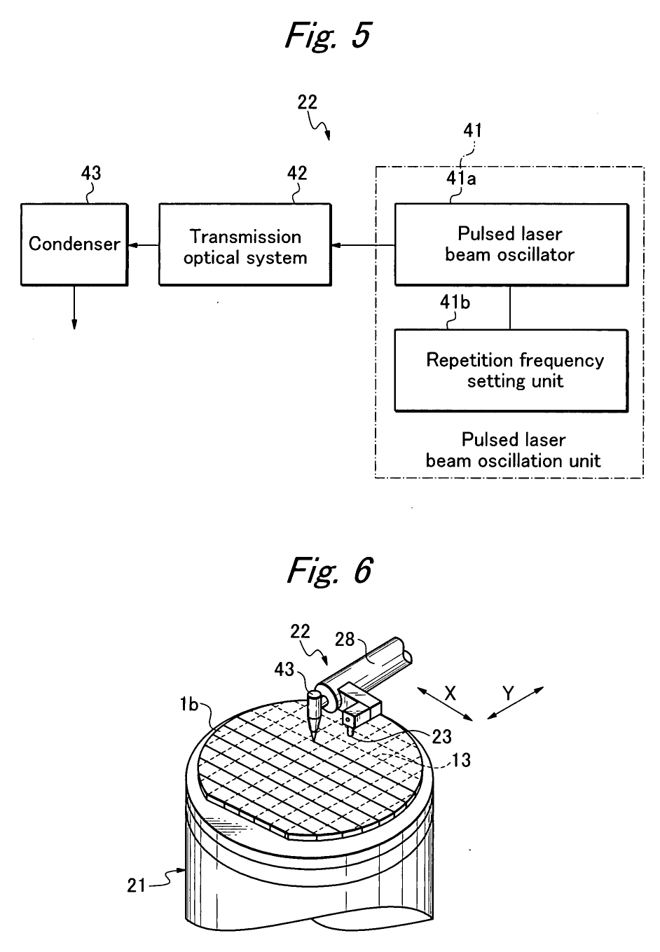

FIG. 4 is a perspective view showing a configuration of part of the laser processing machine, and FIG. 5 is a block diagram showing an example of a configuration of laser beam irradiation unit A laser processing machine 20 used in the embodiment has a chuck table 21 for holding a wafer 1, a laser beam irradiation unit 22 for irradiating a pulsed laser beam having a wavelength transmitted by the wafer 1 held on the chuck table 21, and an imaging unit 23 for imaging the wafer 1 held on the chuck table 21. The chuck table 21 suctionally holds the wafer 1, and is rotatably provided while being connected to a motor 24. Moreover, the chuck table 21 is provided to be movable in an X axis direction being a horizontal direction by a processing feed unit 27 including a ball screw 25, a nut (not shown), a pulse motor 26 and the like, so that the table 21 relatively feeds a wafer 1 mounted thereon with respect to the laser beam irradiation unit 22.

The laser beam irradiation unit 22 includes a cylindrical casing 28 disposed substantially horizontally, and provided to be movable in a Z axis direction by a Z axis movement unit 30 via the casing 28, the unit 30 including a ball screw (not shown), a nut (not shown), a pulse motor 29 and the like. Furthermore, the laser beam irradiation unit 22 is provided to be movable in a Y axis direction being the horizontal direction by an indexing feed unit 34 including a base 31 mounted with the casing 28 and the Z axis movement unit 30, a ball screw 32, a nut (not shown), pulse motor 33 and the like, so that it relatively feeds the laser beam irradiation unit 22 to indexed points of the wafer 1 on the chuck table 21 sequentially.

Here, in the casing 28, a pulsed laser beam oscillation unit 41 and a transmission optical system 42 are arranged as shown in FIG. 5. The pulsed laser beam oscillation unit 41 includes a pulsed laser beam oscillator 41a such as an Yb laser (ytterbium doped fiber laser) oscillator or an Er laser (erbium doped fiber laser) oscillator, and a repetition frequency setting unit 41b accompanying the pulsed laser beam oscillator 41a. The transmission optical system 42 includes optical elements such as a beam splitter, in addition, includes an output adjustment unit such as attenuator. At an end portion of the casing 28, a condenser 43 is equipped, which accommodates a condensing lens (not shown) including a known configuration such as coupling lens.

The imaging unit 23 equipped at the end portion of the casing 28 is to image a surface of the wafer 1 held on the chuck table 21, and detect a region to be processed by a pulsed laser light irradiated from the condenser 43 of the laser beam irradiation unit 22, which has an imaging device (CCD), and sends an imaged image signal to a not-shown control unit.

An affected-zone formation process using such a laser processing machine 20 is described with reference to FIG. 4 and FIGS. 6 to 8. First, as shown in FIG. 6, the wafer 1 is set on the chuck table 21 with a side of the back 1b (sapphire substrate 11) up, then the wafer 1 is suctionally held on the chuck table 21. Preferably, a protective tape is previously attached to a surface 1a of the wafer 1 to be contacted to the chuck table 21. The chuck table 21 suctionally holding the wafer 1 is positioned directly below the imaging unit 23 by the processing feed unit 27 or the indexing feed unit 34.

When the chuck table 21 is positioned directly below the imaging unit 23, the imaging unit 23 and a not-shown control unit perform alignment operation for detecting a processing region to be subjected to laser processing in the wafer 1. That is, the imaging unit 23 and the control unit execute image processing such as pattern matching for performing alignment between predetermined division lines 13 formed in a predetermined direction on the wafer 1 and the condenser 43 of the laser beam irradiation unit 22 for irradiating a pulsed laser light along the predetermined division lines 13 to accomplish alignment of a laser beam irradiation position. At that time, alignment of a laser beam irradiation position is similarly accomplished with respect to predetermined division lines 13, which extend in a direction perpendicular to the predetermined direction, formed on the wafer 1.

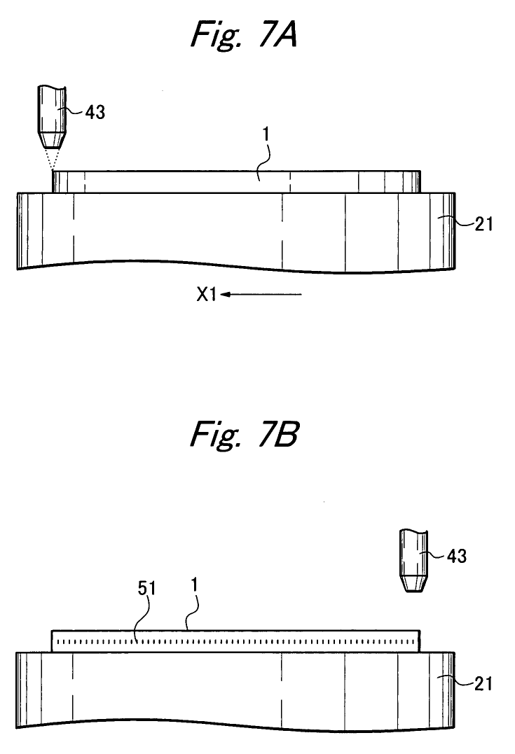

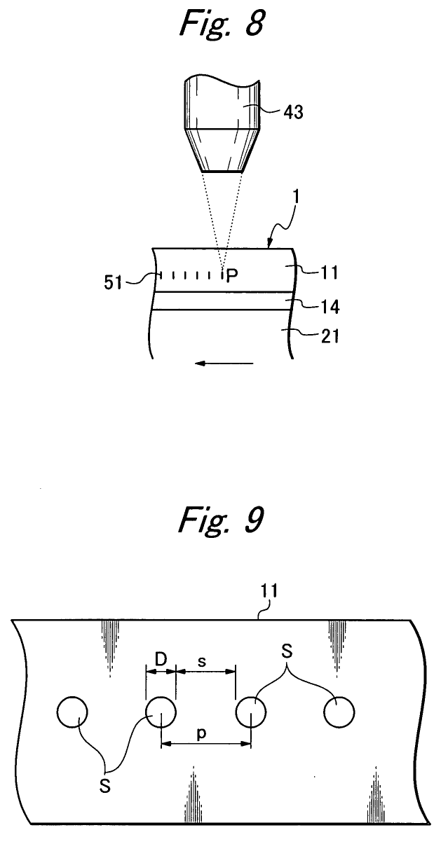

When alignment of the laser beam irradiation position is performed, as shown in FIG. 7A, the chuck table 21 is moved to a laser beam irradiation region where the condenser 43 for irradiating a pulsed laser beam is located, and predetermined one end (left end in FIG. 7A) of the predetermined division lines 13 is positioned directly below the condenser 43. Then, while a pulsed laser beam having a transmittable wavelength is irradiated from the condenser 43, the chuck table 21 or the wafer 1 is moved at a predetermined feed rate in a direction shown by an arrow X1 in FIG. 7A. Then, as shown in FIG. 7B, when an irradiation position of the condenser 43 reaches a position at the other end of the predetermined division lines 13, irradiation of the pulsed laser beam by the laser beam irradiation unit 22 is stopped, and movement of the chuck table 21 or the wafer 1 is stopped. In such an affected-zone formation process, as shown in FIG. 8, a pulsed laser beam is irradiated while a condensing point P of the pulsed laser beam is positioned within each of regions corresponding to the predetermined division lines 13 on the sapphire substrate 11, thereby affected zones 51 are formed. External force is applied to the sapphire substrate 11 along predetermined division lines 13 reduced in strength by continuously forming such affected zones 51, thereby the sapphire substrate 11 can be divided along the predetermined division lines 13, and segmented into individual light emitting devices 12.

Here, for processing conditions used for the affected-zone formation process of the embodiment, examples 1 and 2 are illustrated.

### EXAMPLE 1

### Wavelength: 1045 nm (Yb laser is used)

### Average output 0.23 W

Repetition frequency: 100 kHz
Feed rate: 300 mm/s
Pulse width: 467 fs
Condensing spot size: about 0.9 μm
Pulse energy: 2.3 μJ
Pulse energy density: 360 J/cm²

### Peak power density at condensing point P: 720 TW/cm²

### EXAMPLE 2

### Wavelength: 1560 nm (Er laser is used)

### Average output 0.2 W

Repetition frequency: 100 kHz
Feed rate: 300 mm/s
Pulse width: 1000 fs
Condensing spot size: about 1.4 μm
Pulse energy: 2.0 μJ
Pulse energy density: 130 J/cm²

### Peak power density at condensing point P: 130 TW/cm²

According to the processing condition as illustrated in the examples 1 or 2, a pulsed laser beam having a small pulse energy such as 2.3 μJ or 2.0 μJ, an extremely small pulse width in a range of femto-second such as 467 fs or 1000 fs, and high intensity is irradiated while the condensing point P is positioned within each of regions corresponding to the predetermined division lines 13 on the sapphire substrate 11 so that the affected zones 51 are formed, thereby the laser beam can be irradiated even at a high peak power density of 720 TW/cm² or 130 TW/cm², consequently each of the affected zones 51 can be formed at only a desired condensing point P within the sapphire substrate 11. Thus, a laser beam is transmitted by the sapphire substrate 11 and irradiated to an epitaxial layer formed by the GaN based buffer layer 14a or the n-type GaN based layer 14b located at the surface 1a side, thereby damage to the nitride semiconductors 14 (light emitting device 12), which may degrade device capability, can be reduced, or production of a processing trace, which may attenuate the laser beam, on a divided section of the sapphire substrate 11 after laser processing can be reduced, the divided section being to be part of a light ejection area of the light emitting device 12. In this way, necessary laser processing can be performed such that damage to the divided surface of the nitride semiconductors 14 or the sapphire substrate 11 due to the laser beam irradiation is minimized. Accordingly, reduction in luminance of the light emitting devices 12, which are dividedly formed, can be controlled to be extremely small.

Here, according to knowledge of the inventors, not only in the examples 1 and 2, but more generally, it is important to satisfy

a wavelength of a pulsed laser beam of 1 μm to 2 μm,

pulse energy of 0.6 μJ to 10 μJ,

pulse energy density of 40 J/cm² to 5 kJ/cm², and

peak power density at condensing point of 4×10¹³ W/cm² to 5×10¹⁵ W/cm².

According to such a processing condition, a pulsed laser beam having a small pulse energy of 0.6 μJ to 10 μJ, and an extremely small pulse width in a range of femto-second is irradiated while the condensing point P is positioned within each of regions corresponding to the predetermined division lines 13 on the sapphire substrate 11 so that the affected zones 51 are formed, thereby the laser beam can be irradiated even at an extremely high peak power density of 4×10¹³ W/cm² to 5×10¹⁵ W/cm², consequently each of the affected zones 51 can be formed at only a desired condensing point P within the sapphire substrate 11. Therefore, necessary laser processing can be performed while damage to the nitride semiconductors 14 or the sapphire substrate 11 is minimized, the damage accompanying laser beam irradiation.

In such a processing condition, when it is assumed that repetition frequency of a pulsed laser beam is X Hz, condensing spot size of the pulsed laser beam is D mm, and feed rate by the processing feed unit 27 is V mm/s, they are desirably set such that V/X=2D to 5D is given. Moreover, repetition frequency X and feed rate V are desirably set such that X is 10 Hz to 1 MHz, and V is 10 mm/s to 1000 mm/s.

When a pulsed laser beam having a repetition frequency X is irradiated from the condenser 43 of the laser beam irradiation unit 22 to the sapphire substrate 11 with a condensing spot size D, and the chuck table 21 or the wafer 1 is fed at a feed rate V, when a value of V/X is 1D or less, a pitch of the spot of the pulsed laser beam is not more than condensing spot size D, therefore the beam is continuously irradiated along the predetermined division lines 13 while spots are contacted to or overlapped with one another, consequently the sapphire substrate 11 may be damaged, causing reduction in luminance. On the contrary, when the value of V/X is 2D to 5D, a pitch p of a spot S of the pulsed laser beam is more than the condensing spot size D, and as shown in FIG. 9, a gap is formed between adjacent spots S, consequently the beam is intermittently irradiated along the predetermined division lines 13 while the gap is formed. In the case of V/X=2D, a space s between the adjacent spots S is equal to the condensing spot size D, and in the case of V/X=5D, the space s between the adjacent spots S is 4 times as large as the condensing spot size D. In the case of V/X>5D, the sapphire substrate 11 is hard to be divided, and possibly not divided along the predetermined division lines 13. Therefore, the value of V/X is desirably 2D to 5D.

When the pulsed laser beam is intermittently irradiated such that the gap is formed between the adjacent spots S, and the affected zones 51 are intermittently formed along the predetermined division lines 13, only small stress is required for breaking the sapphire substrate 11, which has the affected zones 51 formed therein and thus has reduced strength, along the predetermined division lines 13, and therefore the sapphire substrate 11 can be divided into the light emitting devices 12 without causing reduction in luminance. That is, an advantage is given in that since an area irradiated with the pulsed laser beam is decreased to the utmost, laser processing can be performed such that strength is reduced along the predetermined division lines 13 while damage to the divided sections of the sapphire substrate 11 is controlled to be minimally necessary, consequently a luminance characteristic of the light emitting device 12 is not degraded.

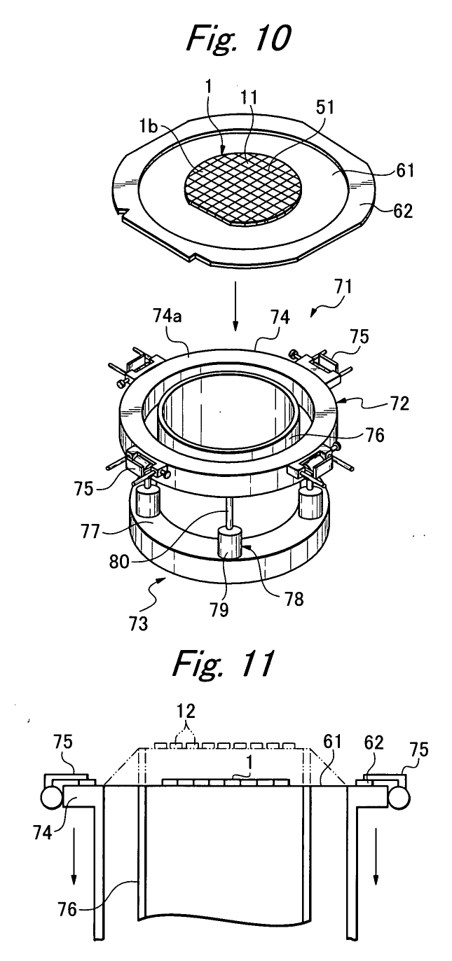

As described above, the affected zones 51 are formed along the predetermined division lines 13 within the sapphire substrate 11 in the affected-zone formation process, so that strength is reduced, then a stretchable protective tape 61 is attached to a back 1b side of the wafer 1, as shown in FIG. 10. That is, a surface of the stretchable protective tape 61, which is mounted on a circular frame 62 at the periphery so as to cover an inside opening of the frame 62, is attached to the back 1b of the wafer 1. As such a protective tape 61, for example, a tape can be used, which is formed by coating acrylic resin based glue at a thickness of about 5 μm on a surface of a sheet base including polyvinyl chloride (PVC) 70 μm in thickness. When a protective tape is attached to the surface 1a in the affected-zone formation process, after the protective tape 61 is attached to the back 1b side, the protective tape attached to the surface 1a side is separated.

Next, a division process is carried out, in which the protective tape 61 attached with the wafer 1 is forcibly stretched, thereby the sapphire substrate 11 is applied with external force and thus divided along the predetermined division lines 13. The division process is carried out using a tape expanding machine 71 as shown in FIG. 11. The tape expanding machine 71 has a frame holding unit 72 for holding the circular frame 62, and a tape expanding unit 73 for expanding the protective tape 61 mounted on the frame 62 held by the frame holding unit 72. The frame holding unit 72 includes a circular frame holding member 74, and a plurality of clamp mechanisms 75 arranged in the periphery of the member 74. The frame holding member 74 has a setting surface 74a for setting the frame 62, and the clamp mechanisms 75 fix the frame 62 set on the setting surface 74a to the frame holding member 74. Such a frame holding unit 72 is supported by the tape expanding unit 73 in a vertically, reversibly movable manner.

The tape expanding unit 73 has an expanding drum 76 arranged inside the frame holding member 74. The expanding drum 76 has an inner diameter smaller than that of the frame 62, and an outer diameter larger than that of the wafer 1. Moreover, the expanding drum 76 has a support flange 77 at a lower end. In addition, the unit 73 has a support unit 78 for supporting the frame holding member 74 in a vertically, reversibly movable manner. The support unit 78 includes a plurality of air cylinders 79 arranged on the support flange 77, and piston rods 80 are connected to a bottom of the frame holding member 74. The support unit 78 vertically moves the frame holding member 74 between a reference position, at which the setting surface 74a is approximately the same in height as an upper end of the expansion drum 76, and an expanding position below the upper end of the expansion drum 76 by a certain length.

Thus, the frame 62 supporting the wafer 1, in which the affected zones 51 have been formed, via the protective tape 61 is set on the setting surface 74a of the frame holding member 74, and fixed to the frame holding member 74 by the clamp mechanisms 75. At that time, the frame holding member 74 is positioned in the reference position (see a condition shown by a solid line in FIG. 11). Next, the plurality of air cylinders 79 are actuated to lower the frame holding member 74 to the expanding position. Thus, since the frame 62 fixed on the setting surface 74a is also lowered, as shown by an imaginary line (two-dot chain line) in FIG. 11, the protective tape 61 mounted on the frame 62 is contacted to an upper edge of the expanding drum 76 and thus applied with external force that expands the tape. At that time, the sapphire substrate 11 of the wafer 1 attached to the protective tape 61 has been reduced in strength because a large number of affected zones 51 were formed along the predetermined division lines 13, therefore the sapphire substrate 11 is applied with tension as external force along the predetermined division lines 13 in which the affected zones 51 are formed, and broken in a cleavage manner with portions of the affected zones 51 as trigger, so that the substrate 11 is divided into the individual light emitting devices 12 (the epitaxial layer formed by the GaN based buffer layer 14a and the n-type GaN based layer 14b, which is left on the sapphire substrate 11, is also broken at the same time because it is extremely thin compared with the sapphire substrate 11). Since the individually divided light emitting devices 12 are left attached on the protective tape 61, they are not separately scattered, and each light emitting device 12 can be picked up later from the protective tape 61.

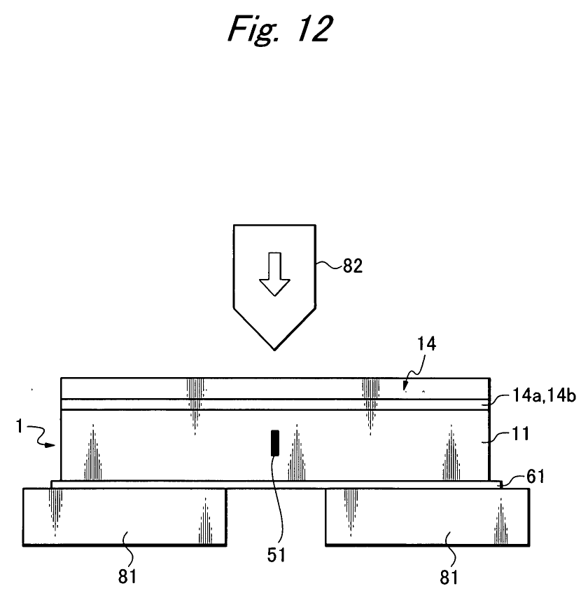

While all the predetermined division lines 13 on the sapphire substrate 11 of the wafer 1 were divided at a time using the tape expanding machine 71 in the example shown in FIGS. 10 and 11, a dividing method is not limited to such a method. For example, as shown in FIG. 12, it is also acceptable that the back 1b (sapphire substrate 11) side of the wafer 1, in which the affected zones 51 were formed, is supported by a support bases 81 at regions somewhat away from the predetermined division line 13 to both ends, and a jig such as sintered hard alloy jig 82 is disposed at a side of the surface 1a (nitride semiconductors 14) of the wafer 1, then external force is applied to the predetermined division lines 13 by one line by the sintered hard alloy jig 82, thereby the sapphire substrate 11 is divided along the predetermined division lines 13.

While the wafer 1 being an object in the affected-zone formation process was described with an example that the epitaxial layer formed by the GaN based buffer layer 14a and the n-type GaN based layer 14b was located on a surface region corresponding to the predetermined division lines 13 on the sapphire substrate 11 (peripheral region of each of the light emitting devices 12) in the embodiment, a wafer may be used as an object, in which the epitaxial layer is previously removed from the surface region corresponding to the predetermined division lines 13 by etching or the like. According to this, even if the pulsed laser beam is irradiated from a side of the sapphire substrate 11 (from the back 1b side of the wafer 1) along the predetermined division lines 13, since a laser beam transmitted by the sapphire substrate 11 does not impinge on the epitaxial layer, the nitride semiconductors 14 are not damaged, and therefore quality of the light emitting device 12 can be improved. Moreover, since the epitaxial layer does not exist in the surface region corresponding to the predetermined division lines 13, and the sapphire substrate 11 is exposed, a pulsed laser beam can be irradiated from the surface 1a side, at which the nitride semiconductors 14 are stacked (from the surface 1a side of the wafer 1), to the inside of the sapphire substrate 11.

Moreover, while the processing feed unit 27 for moving the chuck table 21 in the X axis direction was used, in addition, the indexing feed unit 34 for moving the laser beam irradiation unit 22 in the Y axis direction was used in the laser processing machine 20 used in the embodiment, since movement of the chuck table 21 (wafer 1) and movement of the laser beam irradiation unit 22 are relatively performed, a processing feed unit for moving the laser beam irradiation unit 22 in the X axis direction may be used, in addition, an indexing feed unit for moving the chuck table 21 in the Y axis direction may be used.

1. A method of processing a sapphire substrate for forming affected zones within a plurality of predetermined division lines of light emitting devices, which are formed by stacking nitride semiconductors on a sapphire substrate, using a laser processing machine having
a chuck table for holding a wafer,
a laser beam irradiation unit for irradiating a pulsed laser beam having a wavelength transmitted by the wafer held on the chuck table,
a processing feed unit for relatively feeding the chuck table and the laser beam irradiation unit for carrying out a process, and
an indexing feed unit for relatively feeding the chuck table and the laser beam irradiation unit to indexed points sequentially:
wherein the pulsed laser beam is irradiated at a processing condition satisfying
a wavelength of the pulsed laser beam of 1 μm to 2 μm,
pulse energy of 0.6 μJ to 10 μJ,
pulse energy density of 40 J/cm² to 5 kJ/cm², and
peak power density at condensing point of 4×10¹³ W/cm² to 5×10¹⁵ W/cm²,
while a condensing point is positioned within each of regions corresponding to the predetermined division lines on the sapphire substrate, so that the affected zones are formed.

2. The method of processing the sapphire substrate according to claim 1:
wherein when it is assumed that repetition frequency of the pulsed laser beam is X Hz, condensing spot size of the pulsed laser beam is D mm, and feed rate by the processing feed unit is V mm/s,
V/X is 2D to 5D.

3. The method of processing the sapphire substrate according to claim 2:
wherein repetition frequency X is 10 Hz to 1 MHz, and feed rate V is 10 mm/s to 1000 mm/s.

4. The method of processing the sapphire substrate according to claim 1:
wherein after the affected zones are formed within the sapphire substrate, the sapphire substrate is applied with external force to be divided along the predetermined division lines.

5. The method of processing the sapphire substrate according to claim 2:
wherein after the affected zones are formed within the sapphire substrate, the sapphire substrate is applied with external force to be divided along the predetermined division lines.

6. The method of processing the sapphire substrate according to claim 3:
wherein after the affected zones are formed within the sapphire substrate, the sapphire substrate is applied with external force to be divided along the predetermined division lines.
